(19) United States
(12) Patent Application Publication
(10) Pub. No.: US 2013/0099351 A1
(43) Pub. Date: Apr. 25, 2013

(54) BIPOLAR TRANSISTOR AND METHOD OF MANUFACTURING THE SAME

(71) Applicant: SHANGHAI HUA HONG NEC ELECTRONICS CO., LTD, Shanghai (CN)

(72) Inventors: Fan Chen, Shanghai (CN); Xiongbin Chen, Shanghai (CN); Kai Xue, Shanghai (CN); Keran Zhou, Shanghai (CN); Jia Pan, Shanghai (CN); Hao Li, Shanghai (CN); Yongcheng Wang, Shanghai (CN)

(73) Assignee: SHANGHAI HUA HONG NEC ELECTRONICS CO., LTD, Shanghai (CN)

(21) Appl. No.: 13/658,167

(22) Filed: Oct. 23, 2012

(30) Foreign Application Priority Data
Oct. 24, 2011 (CN) 201110326334.4

(51) Int. Cl. H01L 29/73; H01L 21/331

(52) U.S. Cl. 257/526; 438/361; 257/E21.37; 257/E29.174

(57) ABSTRACT

A bipolar transistor is disclosed, which includes a collector region, a base region, an emitter region and field plates. Each field plate is present in a structure of a flat sidewall covering one side face of the active region so that it also covers the collector region from one side. The field plate has its surface parallel to the side face of the active region and is isolated from the side face of the active region by a pad oxide layer. The field plate has its top lower than the surface of the active region. The bipolar transistor is capable of improving the breakdown voltage of the device without increasing the collector resistance or deteriorating the frequency characteristic. A method of manufacturing bipolar transistor is also disclosed.

### CROSS-REFERENCES TO RELATED APPLICATIONS

This application claims the priority of Chinese patent application number 201110326334.4, filed on Oct. 24, 2011, the entire contents of which are incorporated herein by reference.

### TECHNICAL FIELD

The present invention relates to the fabrication of semiconductor integrated circuits, and more particularly, to a bipolar transistor and manufacturing method thereof.

### BACKGROUND

According to their application requirements, bipolar transistor devices are mainly categorized into high-speed devices and high-voltage devices, wherein high-voltage devices are required to achieve a maximum BVceo while maintaining a relatively high cut-off frequency. FIG. 1 shows the structure of an existing bipolar transistor, which is formed on a silicon substrate 1 having an active region isolated by shallow trench field oxides 3. The bipolar transistor includes: a collector region 4 composed of an ion implantation region of a first conductivity type formed in the active region; a base region 5 of a second conductivity type, which is formed on the surface of the active region and is in contact with the collector region 4; an emitter region 6 of the first conductivity type, which is formed on the surface of the base region 5 and is in contact with the base region 5; and a buried layer 2 of the first conductivity type, which is formed beneath the bottoms of the shallow trench field oxides 3 and is in contact with the collector region 4 so as to connect the collector region 4 to a pick-up region 2a of the first conductivity type formed in another active region in the silicon substrate 1. The collector region 4 is picked up through a metal contact formed in the another active region. For a PNP transistor, the first conductivity type is P type and the second conductivity type is N type. For an NPN transistor, the first conductivity type is N type and the second conductivity type is P type.

FIG. 2 schematically illustrates a triode region of the existing bipolar transistor device shown in FIG. 1. FIG. 3 is a schematic illustration of the distribution of electric field intensities of a collector junction, namely the PN junction between the base region and the collector region, of the existing bipolar transistor device shown in FIG. 2. In FIG. 3, the coordinates of the horizontal axis correspond to positions within the PN junction between the base region and the collector region; the coordinates of the vertical axis correspond to electric field intensities at different positions within the PN junction between the base region and the collector region; the origin of the coordinates corresponds to the contact position between the base region 5 and the collector region 4. In current practices, the BVceo is improved by reducing the doping concentration of the collector region 4, which is a simple and effective method. Taking an NPN transistor as an example, the BVceo is measured by continuously increasing the voltage of the collector region 4 when the forward bias between the base region 5 and the emitter region 6 is turned on, so that the electric field intensity between the base region 5 and the collector region 4 will also continuously increase. As a result, the electrons implanted from the emitter region 6 into the base region 5 will enter the high electric field intensity region of the collector junction and eventually cause an avalanche due to the collision ionization of the electrons. The voltage between the collector region 4 and the emitter region 6 at the point of avalanche is recorded as the BVceo. As indicated by FIG. 3, the electric field intensities within the collector region 4 undergo a linear decrease from a peak value at the contact position between the base region 5 and the collector region 4 to zero at the body part of the collector region 4. Since the breakdown voltage is determined by the peak value of the electric field intensities, it is possible to increase the breakdown voltage by lowering the peak electric field intensity of the collector junction through reducing the doping concentration of the collector region 4. However, as this method increases the resistance of the collector region 4, it leads to significant decrease of the cut-off frequency of the transistor while increasing its breakdown voltage, making the performance unsatisfactory.

### SUMMARY OF THE INVENTION

An objective of the present invention is to provide a bipolar transistor which is capable of improving the breakdown voltage of the device without increasing the collector resistance or deteriorating the frequency characteristic.

Another objective of the present invention is to provide a method of manufacturing such bipolar transistors.

To achieve the above objectives, one aspect of the present invention provides a bipolar transistor, formed on a silicon substrate, the silicon substrate having an active region isolated by shallow trench field oxides, the bipolar transistor including: a collector region formed of an ion implantation region of a first conductivity type in the active region; a base region of a second conductivity type formed on a surface of the active region, the base region being in contact with the collector region; an emitter region of the first conductivity type formed on a surface of the base region, the emitter region being in contact with the base region, wherein the bipolar transistor further includes field plates covering side faces of the active region, each of the field plates having its surface parallel to one side face of the active region and being isolated from the side face of the active region by a pad oxide layer, the field plate having its top lower than the surface of the active region.

In a preferred embodiment, the field plate is a polysilicon field plate.

In a preferred embodiment, the bipolar transistor further includes a buried layer of the first conductivity type formed beneath bottoms of the shallow trench field oxides, the buried layer being in contact with the collector region and connecting the collector region to another active region in the silicon substrate so as to pick up the collector region through a metal contact formed in the another active region.

When the bipolar transistor is a PNP transistor, the first conductivity type is P type and the second conductivity type is N type; and when the bipolar transistor is an NPN transistor, the first conductivity type is N type and the second conductivity type is P type.

Another aspect of the present invention provides a method of manufacturing bipolar transistor, which includes:

forming shallow trenches in a silicon substrate, an active region being isolated by the shallow trenches;

forming a pad oxide layer covering bottoms and sidewalls of the shallow trenches;

forming a field plate in each of the shallow trenches to cover both side faces of the active region, the field plate having its surface parallel to one side face of the active region and being isolated from the side face of the active region by the pad oxide layer, the field plate having its top lower than a surface of the active region;

filling field oxide into the shallow trenches;

forming a collector region in the active region by ion implantation of a first conductivity type;

forming a base region of a second conductivity type on the surface of the active region, the base region being in contact with the collector region; and

forming an emitter region of the first conductivity type on a surface of the base region, the emitter region being in contact with the base region.

In a preferred embodiment, forming shallow trenches in a silicon substrate includes:

forming a silicon nitride hard mask layer on a surface of the silicon substrate;

removing part of the silicon nitride hard mask layer by etch to form shallow trench etch windows; and

forming shallow trenches by etching in the shallow trench etch windows.

In a preferred embodiment, forming a field plate in each of the shallow trenches includes:

growing polysilicon on the surface of the silicon substrate, the polysilicon covering the pad oxide layer on bottoms and sidewalls of the shallow trenches and covering the silicon nitride hard mask layer on the surface of the active region; and

removing the polysilicon on the silicon nitride hard mask layer and on the bottoms of the shallow trenches and etching a top of the polysilicon on sidewalls of the shallow trenches to a height lower than the surface of the active region to form the field plates.

In a preferred embodiment, the method further includes forming a buried layer of the first conductivity type beneath bottoms of the shallow trenches after forming the shallow trenches and before forming the pad oxide layer, the buried layer being in contact with the collector region and connecting the collector region to another active region in the silicon substrate so as to pick up the collector region through a metal contact formed in the another active region.

In the bipolar transistor of the present invention, each side face of the collector region is covered with a field plate to smooth the distribution of electric field intensities within the collector junction, namely the PN junction between the base region and the collector region, in this way, the peak electric field intensity within the collector junction is lowered, and the breakdown voltage of the device is increased without increasing the collector resistance or deteriorating the frequency characteristic.

### BRIEF DESCRIPTION OF THE DRAWINGS

The present invention will be described and specified below with reference to accompanying drawings and exemplary embodiments.

FIG. 1 is a schematic illustration of a bipolar transistor of the prior art.

FIG. 2 is a schematic illustration of a triode region of the bipolar transistor of the prior art shown in FIG. 1.

FIG. 3 is a schematic illustration of the distribution of electric field intensities within a collector junction of the bipolar transistor of the prior art shown in FIG. 2.

FIG. 4 is a schematic illustration of the bipolar transistor according to an embodiment of the present invention.

FIG. 5 and FIG. 6 schematically illustrate the structures of the bipolar transistor in various steps of the manufacturing method according to an embodiment of the present invention.

FIG. 7 is a schematic illustration of a triode region of the bipolar transistor shown in FIG. 4 according to an embodiment of the present invention.

FIG. 8 is a schematic illustration of the distribution of electric field intensities within a collector junction of the bipolar transistor shown in FIG. 7 according to an embodiment of the present invention.

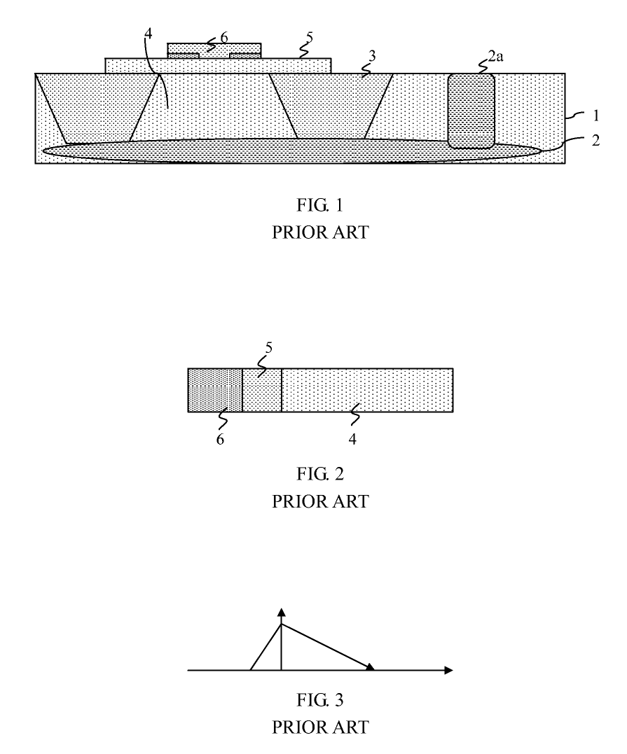

### DETAILED DESCRIPTION

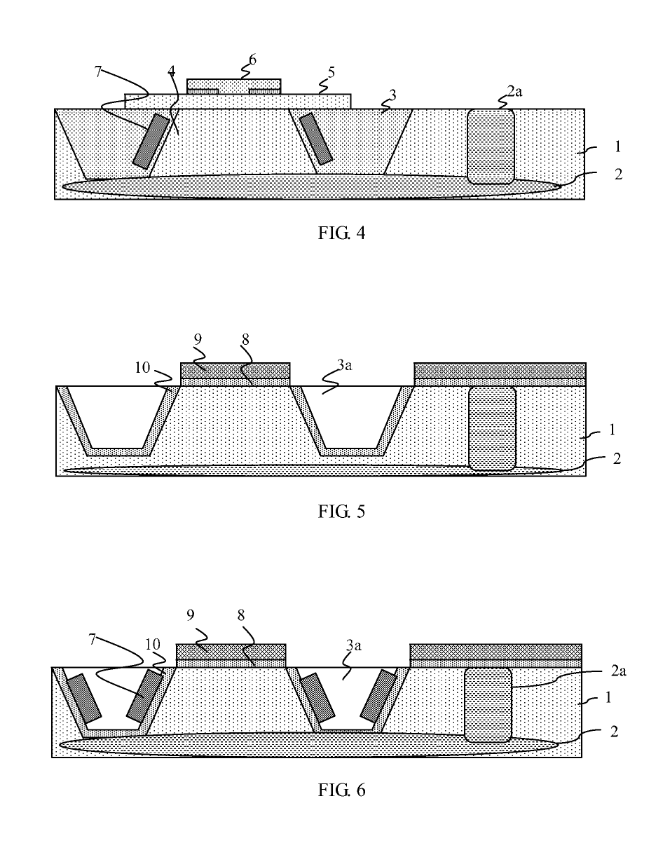

FIG. 4 illustrates the structure of the bipolar transistor according to a preferred embodiment of the present invention. The bipolar transistor is provided on a silicon substrate 1, in which an active region is isolated by shallow trench field oxides 3. The bipolar transistor includes: a collector region 4 formed of an ion implantation region of a first conductivity type in the active region; a base region 5 of a second conductivity type formed on the surface of the active region and being in contact with the collector region 4; an emitter region 6 of the first conductivity type formed on the surface of the base region 5 and being in contact with the base region 5; and a buried layer 2 of the first conductivity type formed beneath the bottoms of the shallow trench field oxides 3. The buried layer 2 is in contact with the collector region 4 so as to connect the collector region 4 to a pick-up region 2a of the first conductivity type formed in another active region. The collector region 4 is picked up through a metal contact formed in the another active region.

According to a preferred embodiment, the bipolar transistor further includes field plates 7, which are preferably polysilicon field plates. Each of the field plates 7 is present in a structure of a flat sidewall covering one side face of the active region so that it also covers the collector region 7 from one side. The field plate 7 has its surface parallel to the side face of the active region and is isolated from the side face of the active region by a pad oxide layer. The field plate 7 has its top lower than the surface of the active region.

In the above structure, when the bipolar transistor is a PNP transistor, the first conductivity type is P type and the second conductivity type is N type; when the bipolar transistor is an NPN transistor, the first conductivity type is N type and the second conductivity type is P type.

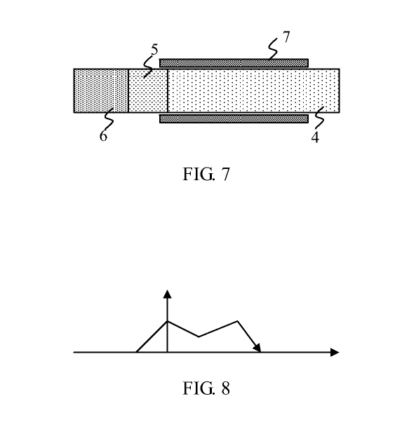

FIG. 5 and FIG. 6 schematically illustrate the structures of the device in various steps of the manufacturing method according to a preferred embodiment of the present invention. The manufacturing method includes the following steps:

First, perform a step of forming shallow trenches 3a, which includes: growing in sequence a sacrificial oxide layer 8 and a silicon nitride hard mask layer 9 on the surface of the silicon substrate 1; removing part of the layers 8 and 9 by etch to form shallow trench etch windows so as to expose the regions where the shallow trenches 3a are to be formed while keeping the active region covered by the remaining silicon nitride hard mask layer 9; then etching in the shallow trench etch windows, namely etching the substrate 1 by using the silicon nitride hard mask layer 9 as a mask, to form shallow trenches 3a in the substrate 1.

Second, form a buried layer 2 of a first conductivity type in the substrate 1. The location of the buried layer 2 is under the bottoms of the shallow trenches 3a. The buried layer 2 is used to form contact with a collector region 4 to be formed subsequently so as to connect the collector region 4 to a pick-up region 2a of the first conductivity type formed in another active region and to pick up the collector region 4 through a metal contact formed in the another active region.

After that, perform a step of forming field plates over side faces of the active region, which includes:

step 1: form a pad oxide layer 10 over the bottom and the side walls of each shallow trench 3a, as shown in FIG. 5;

step 2: grow a polysilicon layer on the surface of the silicon substrate 1, the polysilicon layer covering the pad oxide layer 10 formed over the bottom and the sidewalls of each shallow trench 3a and covering the silicon nitride hard mask layer 9 formed on the surface of the active region;

step 3: remove the part of the polysilicon layer covering the silicon nitride hard mask layer 9 and covering the bottoms of the shallow trenches 3a, namely only remain the part of the polysilicon layer covering the sidewalls of the shallow trenches 3a, and simultaneously reduce the height of the top of the polysilicon on the sidewalls of the shallow trenches 3a to a height lower than the surface of the active region by etch. The remaining polysilicon after etch forms the field plates 7, as shown in FIG. 6.

Afterwards, the method may further include: fill oxide into the shallow trenches 3a to form shallow trench field oxides 3; form a collector region 4 of a first conductivity type by ion implantation into the active region; form a base region 5 of a second conductivity type on the surface of the active region, the base region 5 being in contact with the collector region 4; and form an emitter region 6 of the first conductivity type on the surface of the base region 5, the emitter region 6 being in contact with the base region 5.

In the above steps, when the bipolar transistor is a PNP transistor, the first conductivity type is P type and the second conductivity type is N type; when the bipolar transistor is an NPN transistor, the first conductivity type is N type and the second conductivity type is P type.

FIG. 7 is a schematic illustration of a triode region of the bipolar transistor shown in FIG. 4 according to an embodiment of the present invention. FIG. 8 is a schematic illustration of the electric field intensities within a collector junction, namely, the PN junction between the base region and the collector region, of the bipolar transistor shown in FIG. 7 according to an embodiment of the present invention. In FIG. 8, the coordinates of the horizontal axis correspond to positions within the PN junction between the base region and the collector region; the coordinates of the vertical axis correspond to electric field intensities at different positions within the PN junction between the base region and the collector region; the origin of the coordinates corresponds to the contact position between the base region and the collector region. As shown in FIG. 8, the distribution of the electric field intensities within the collector junction is much smoother compared with the prior art shown in FIG. 3 and has multiple peaks. By smoothing the distribution of electric field intensities within the collector junction, the peak electric field intensity is significantly reduced. As the actual breakdown point of a bipolar transistor is dependent on the maximum peak electric field intensity, the present invention is capable of increasing the breakdown voltage of the device by reducing the peak electric field intensity of the collector junction. Moreover, the breakdown voltage can be improved without increasing the collector resistance or deteriorating the frequency characteristic of the device.

The above specific embodiments are provided for the purpose of describing the invention solely and are not intended to limit the scope of the invention in any way. Those skilled in the art can make various variations and modifications without departing from the spirit or scope of the invention. Thus, it is intended that the present invention cover these modifications and variations.

What is claimed is:

1. A bipolar transistor, formed on a silicon substrate, the silicon substrate having an active region isolated by shallow trench field oxides, the bipolar transistor comprising:
a collector region formed of an ion implantation region of a first conductivity type in the active region;
a base region of a second conductivity type formed on a surface of the active region, the base region being in contact with the collector region; and
an emitter region of the first conductivity type formed on a surface of the base region, the emitter region being in contact with the base region,
wherein the bipolar transistor further comprises field plates covering side faces of the active region, each of the field plates having its surface parallel to one side face of the active region and being isolated from the side face of the active region by a pad oxide layer, the field plate having its top lower than the surface of the active region.

2. The bipolar transistor according to claim 1, wherein the field plate is a polysilicon field plate.

3. The bipolar transistor according to claim 1, further comprising a buried layer of the first conductivity type formed beneath bottoms of the shallow trench field oxides, the buried layer being in contact with the collector region and connecting the collector region to another active region in the silicon substrate so as to pick up the collector region through a metal contact formed in the another active region.

4. The bipolar transistor according to claim 1, wherein when the bipolar transistor is a PNP transistor, the first conductivity type is P type and the second conductivity type is N type; and when the bipolar transistor is an NPN transistor, the first conductivity type is N type and the second conductivity type is P type.

5. A method of manufacturing bipolar transistor, comprising:
forming shallow trenches in a silicon substrate, an active region being isolated by the shallow trenches;
forming a pad oxide layer covering bottoms and sidewalls of the shallow trenches;
forming a field plate in each of the shallow trenches, the field plate having its surface parallel to one side face of the active region and being isolated from the side face of the active region by the pad oxide layer, the field plate having its top lower than a surface of the active region;
filling field oxide into the shallow trenches;
forming a collector region in the active region by ion implantation of a first conductivity type;
forming a base region of a second conductivity type on the surface of the active region, the base region being in contact with the collector region; and
forming an emitter region of the first conductivity type on a surface of the base region, the emitter region being in contact with the base region.

6. The method according to claim 5, wherein forming shallow trenches in a silicon substrate comprises:
forming a silicon nitride hard mask layer on a surface of the silicon substrate;
removing part of the silicon nitride hard mask layer by etch to form shallow trench etch windows; and
forming shallow trenches by etching in the shallow trench etch windows.

7. The method according to claim 6, wherein forming a field plate in each of the shallow trenches comprises:
growing polysilicon on the surface of the silicon substrate, the polysilicon covering the pad oxide layer on bottoms and sidewalls of the shallow trenches and covering the silicon nitride hard mask layer on the surface of the active region; and
removing the polysilicon on the silicon nitride hard mask layer and on the bottoms of the shallow trenches and etching a top of the polysilicon on sidewalls of the shallow trenches to a height lower than the surface of the active region to form the field plates.

8. The method according to claim 5, further comprising forming a buried layer of the first conductivity type beneath bottoms of the shallow trenches after forming the shallow trenches and before forming the pad oxide layer, the buried layer being in contact with the collector region and connecting the collector region to another active region in the silicon substrate so as to pick up the collector region through a metal contact formed in the another active region.

9. The method according to claim 5, wherein when the bipolar transistor is a PNP transistor, the first conductivity type is P type and the second conductivity type is N type; and
when the bipolar transistor is an NPN transistor, the first conductivity type is N type and the second conductivity type is P type.
